(19) United States
(12) Patent Application Publication
(10) Pub. No.: US 2026/0304606 A1
(43) Pub. Date: Oct. 1, 2026

(54) CIRCUIT BOARD AND SEMICONDUCTOR PACKAGE COMPRISING SAME

(71) Applicant: LG INNOTEK CO., LTD., Seoul (KR)

(72) Inventors: Jong Bae SHIN, Seoul (KR); Moo Seong KIM, Seoul (KR); Woo Jin KIM, Seoul (KR)

(73) Assignee: LG INNOTEK CO., LTD., Seoul (KR)

(21) Appl. No.: 19/490,065

(22) PCT Filed: Jun. 10, 2024
(86) PCT No.: PCT/KR2024/007865

§ 371 Date: Dec. 4, 2025

(30) Foreign Application Priority Data
Jun. 22, 2023 (KR) 10-2023-0080083

(51) Int. Cl. H05K 1/02; H05K 1/185

(52) U.S. Cl. CPC H05K 1/0284; H05K 1/185

(57) ABSTRACT

An embodiment of the present invention provides a circuit board comprising: a core layer comprising a cavity; and a connection member disposed in the cavity of the core layer. The cavity's side surface comprises multiple side surfaces facing multiple side surfaces of the connection member. Each of the multiple side surfaces of the cavity includes a first portion spaced apart from the connection member in the horizontal direction by a predetermined distance along the circumference of the connection member, and a second portion disposed closer to the connection member than the first portion. The second portions of the multiple side surfaces of the cavity overlap the connection member along the horizontal direction.

### CROSS REFERENCE TO RELATED APPLICATIONS

This application is the National Phase of PCT International Application No. PCT/KR 2024/007865, filed on Jun. 10, 2024, which claims priority under 35 U.S.C. 119(a) to Patent Application No. 10-2023-0080083, filed in the Republic of Korea on Jun. 22, 2023, all of which are hereby expressly incorporated by reference into the present application.

### TECHNICAL FIELD

Embodiments according to the present invention relate to a circuit board and a semiconductor package.

### BACKGROUND ART

As the performance of electric/electronic products progresses, technologies for attaching a larger number of packages to a substrate of a limited size are proposed and researched. However, since a general package is based on mounting a single semiconductor chip, there is a limit to obtaining desired performance.

A general circuit board or package substrate has a form in which a processor package having a processor chip disposed thereon and a memory package having a memory chip attached thereto are connected as one. Such a package substrate has an advantage in that, by manufacturing the processor chip and the memory chip as a single integrated package, a mounting area of the chips can be reduced and high-speed signal transmission can be achieved through a shortened path. Due to such an advantage, the above-described package substrate is widely applied to mobile devices and the like.

Meanwhile, in recent years, due to the increasing specifications of electronic devices such as mobile devices and the adoption of high bandwidth memory (HBM), package sizes are increasing. In addition, as the functions required by an application processor increase, there is a demand for configuring the application processor into separate processor chips according to respective functions and providing a circuit board capable of mounting the processor chips. In this case, even when the application processor is divided into two processor chips by function, the number of (input/output) terminals provided in each processor chip is increasing.

Moreover, due to 5G, the Internet of Things (IoT), higher display resolution, increased communication speeds, and the like, as the number of power and signals increases, the number of terminals on processor chips is gradually increasing. Accordingly, the area and thickness of the circuit board, as well as the density of circuit patterns, are also increasing. When the area or thickness of the circuit board increases, problems such as difficulty in product miniaturization, reliability against warpage of the circuit board or the like, and increased product cost may occur. Accordingly, increasing the density of circuit patterns, rather than increasing the area or thickness of the circuit board, is more advantageous in terms of product cost, reliability against warpage or the like, and product miniaturization. Accordingly, miniaturization of circuit patterns and through-electrodes is required.

Further, when connecting a substrate and chips using a bridge, it is difficult to mount the bridge at an accurate position without error.

### DISCLOSURE

### Technical Problem

Embodiments of the present invention provide a circuit board and a semiconductor package including the same, which are capable of effectively preventing an alignment defect in an electronic device through convex portions that protrude toward the inside of a cavity.

Further, embodiments may provide a circuit board and a semiconductor package including the same, in which manufacturability is ensured by including convex portions having the same radius of curvature.

Further, embodiments may provide a circuit board and a semiconductor package including the same, in which detachment and positional alignment of a connection member are precisely performed through a positional relationship between the connection member and convex portions.

Objectives to be solved by the embodiment are not limited to the above-described objectives and will include objectives and effectiveness which may be identified by solutions for the objectives and the embodiments described below.

### Technical Solution

A circuit board according to embodiments of the present invention includes a core layer including a cavity, and a connection member disposed in the cavity of the core layer, wherein side surfaces of the cavity include a plurality of side surfaces facing a plurality of side surfaces of the connection member, each of the plurality of side surfaces of the cavity includes a first portion having a constant separation distance from the connection member in a horizontal direction along a perimeter of the connection member, and a second portion disposed closer to the connection member than the first portion, and the second portion of each of the plurality of side surfaces of the cavity overlaps the connection member in the horizontal direction.

The cavity may include first convex portions and second convex portions that protrude from the side surface of the cavity toward an inner side of the cavity.

The first convex portions may have a greater extension length than the second convex portions and may be adjacent to both end portions of the side surface.

The second portions of the plurality of side surfaces of the cavity may overlap each other in the horizontal direction.

The first convex portions may be disposed closer to the connection member than the second convex portions.

The second convex portions may be disposed between the first convex portions that are adjacent to each other in one direction.

A radius of curvature of the first convex portion may be equal to a radius of curvature of the second convex portion.

An outermost portion of the first convex portion may be disposed on the same line as an outermost portion of the second convex portion.

An innermost portion of the first convex portion may be disposed at the same height from an upper surface or a lower surface of the core layer as an innermost portion of the second convex portion.

The circuit board may include a filling member surrounding the connection member in the cavity.

A height difference between an upper surface of the connection member and an upper surface of the core layer may be greater than a height difference between a lower surface of the connection member and a lower surface of the core layer.

An innermost portion of the first convex portion may be closer to an upper surface of the connection member than to a lower surface of the connection member.

A center of the connection member in a stacking direction may be disposed to be offset from an innermost portion of the first convex portion.

The circuit board may include a die via electrode disposed above the connection member and disposed in a die via passing through the filling member.

A separation distance between the innermost portion of the first convex portion and the die via electrode may be less than or equal to 0.5 times a height of the connection member.

### Advantageous Effects

Embodiments of the present invention implement a circuit board and a semiconductor package including the same, which can effectively prevent an alignment defect in an electronic device.

Further, embodiments can implement a circuit board and a semiconductor package including the same, in which manufacturability is ensured.

Further, embodiments can implement a circuit board and a semiconductor package including the same, in which detachment and alignment of a connection member are precisely performed.

Various advantages and effects of the present invention are not limited to the above description and can be more easily understood through the description of specific embodiments of the present invention.

### DESCRIPTION OF DRAWINGS

FIG. 1 is a cross-sectional view of a circuit board according to a first embodiment of the present invention.

FIG. 2 is a view illustrating a core layer and a first electrode portion in the circuit board according to the first embodiment.

FIG. 3 is a plan view of the core layer and the first electrode portion in the circuit board according to the first embodiment.

FIG. 4 is an enlarged view of portion K in FIG. 3.

FIG. 5 is a cross-sectional view taken along line AA′ of FIG. 3.

FIG. 6 is a cross-sectional view taken along line BB′ of FIG. 3.

FIG. 7 is a cross-sectional view illustrating the core layer, the first electrode portion, a filling member, and a connection member in the circuit board according to the first embodiment.

FIG. 8 is a cross-sectional view taken along line CC′ of FIG. 7.

FIG. 9 is a cross-sectional view taken along line DD′ of FIG. 7.

FIGS. 10 to 14 are views illustrating a method of manufacturing the circuit board according to the first embodiment.

FIG. 15 is a plan view of a circuit board according to a second embodiment.

FIG. 16 is a cross-sectional view taken along line EE′ of FIG. 15.

FIG. 17 is a plan view of a circuit board according to a third embodiment.

FIG. 18 is a cross-sectional view taken along line FF′ of FIG. 17.

FIG. 19 is a cross-sectional view illustrating a semiconductor package according to a first embodiment.

FIG. 20 is a cross-sectional view illustrating a semiconductor package according to a second embodiment.

FIG. 21 is a cross-sectional view illustrating a semiconductor package according to a third embodiment.

FIG. 22 is a cross-sectional view illustrating a semiconductor package according to a fourth embodiment.

### MODES OF THE INVENTION

While the present invention is susceptible to various modifications and alternative forms, particular embodiments thereof are shown by way of example in the drawings and will herein be described in detail. It should be understood, however,
that there is no intent to limit the present invention to the particular forms disclosed, but on the contrary, the present invention is to cover particular modifications, equivalents, and alternatives falling within the spirit and scope of the present invention.

It will be understood that, although the terms “second,” “first,” and the like may be used herein to describe various components, these components should not be limited by these terms. These terms are only used to distinguish one component from another. For example, a first component could be termed a second component, and a second component could similarly be termed a first component without departing from the scope of the present invention. As used herein, the term “and/or” includes any and all combinations of one or more of the associated listed items.

It will be understood that when a component is referred to as being “connected” or “coupled” to another component, it can be directly connected or coupled to the another component or intervening components may be present. In contrast, when a component is referred to as being “directly connected” or “directly coupled” to another component, there are no intervening components present.

The terms used herein are for the purpose of describing particular embodiments only and are not intended to be limiting to the present invention. A singular expression includes a plural expression unless the context clearly indicates otherwise. In the present application, it will be further understood that the terms “comprise,” “comprising,” “include,” and/or “including”, when used in this specification, specify the presence of stated features, integers, steps, operations, elements, components and/or groups thereof but do not preclude the presence or addition of one or more other features, integers, steps, operations, elements, components and/or groups thereof.

Terms, such as those defined in commonly used dictionaries, should be interpreted as having a meaning that is consistent with their meaning in the context of the relevant art and will not be interpreted in an idealized or overly formal sense unless clearly defined in the present application. It should be further understood that terms, such as those defined in commonly used dictionaries, should be interpreted as having a meaning that is consistent with their meaning in the context of the relevant art and are not to be interpreted in an idealized or overly formal sense unless expressly so defined herein.

Hereinafter, embodiments will be described in detail with reference to the accompanying drawings. Regardless of reference numerals, like numbers refer to like components throughout the description of the figures, and the description of the same components will be not reiterated.

Before describing the embodiment, an electronic device to which a semiconductor package of the embodiment is applied will be briefly described. The electronic device includes a main board (not shown). The main board may be physically and/or electrically connected to various components. For example, the main board may be connected to the semiconductor package of the embodiment. Various connection members (e.g., semiconductor devices) may be mounted on the semiconductor package.

The connection members may include an active device and/or a passive device. The active device may be a semiconductor chip in the form of an integrated circuit (IC) in which hundreds to millions of devices are integrated in one chip. The connection member may be a logic chip, a memory chip, or the like. The logic chip may be a central processor (CPU), a graphics processor (GPU), or the like. For example, the logic chip may be an application processor (AP) chip including at least one of a central processor (CPU), a graphics processor (GPU), a digital signal processor, a cryptographic processor, a microprocessor, and a microcontroller, may be an analog-digital converter, an application-specific IC (ASIC), or the like, or may be a chip set including a specific combination of those listed so far.

The memory chip may be a stack memory such as a high-bandwidth memory (HBM). Further, the memory chip may include a memory chip such as a volatile memory (e.g., DRAM), a non-volatile memory (e.g., ROM), a flash memory, or the like.

Meanwhile, a product group to which the semiconductor package of the embodiment is applied may be any one of CSP (Chip Scale Package), FC-CSP (Flip Chip-Chip Scale Package), FC-BGA (Flip Chip Ball Grid Array), POP (Package on Package), and SIP (System in Package), but the present invention is not limited thereto.

In addition, the electronic device may be a smart phone, a personal digital assistant, a digital video camera, a digital still camera, a vehicle, a high-performance server, a network system, computer, monitor, tablet, laptop, netbook, television, video game, smart watch, automotive, or the like. However, the electronic device is not limited thereto, and may be any other electronic device that processes data in addition to these devices.

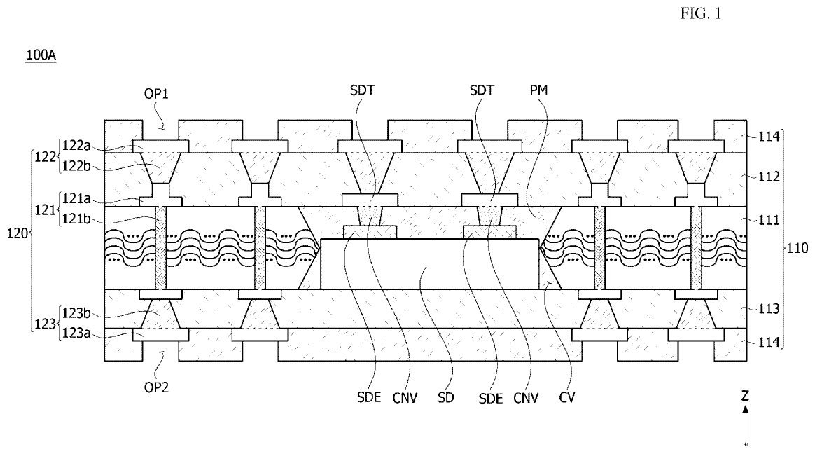

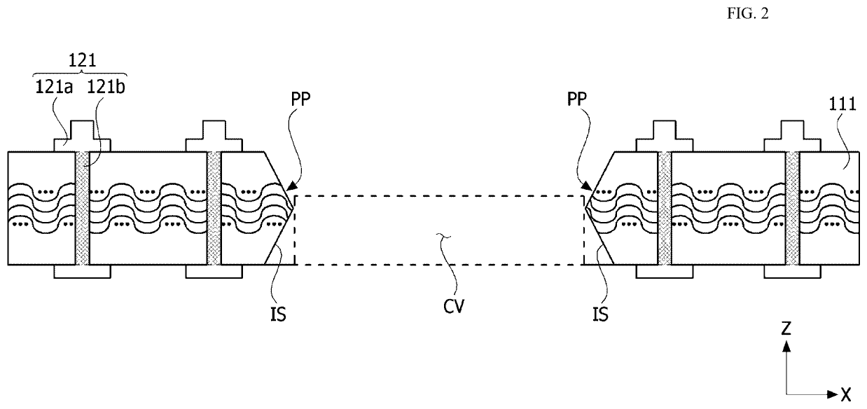

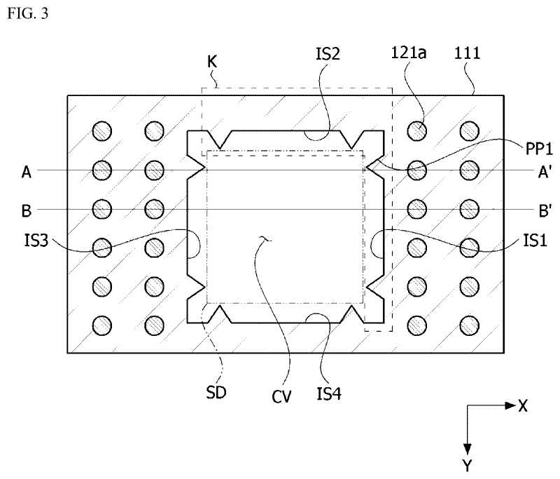

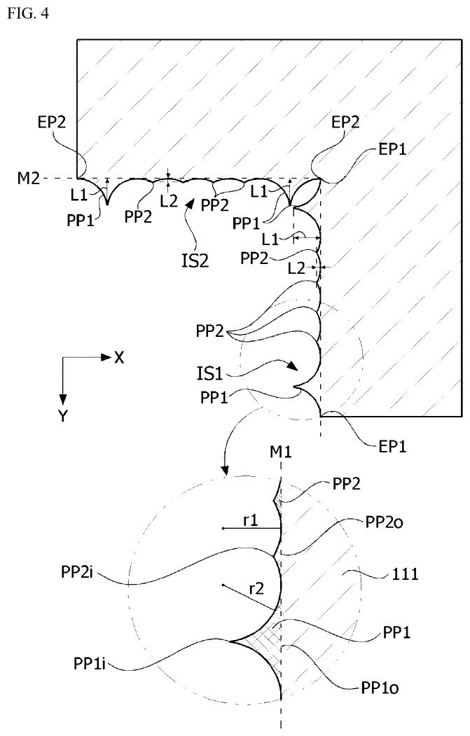

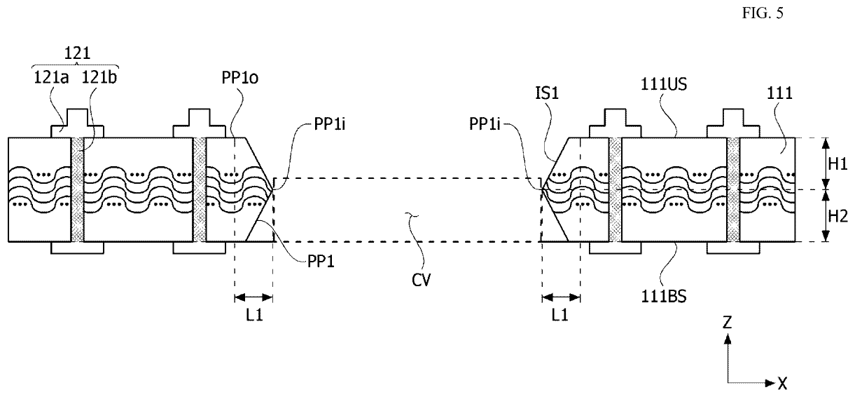

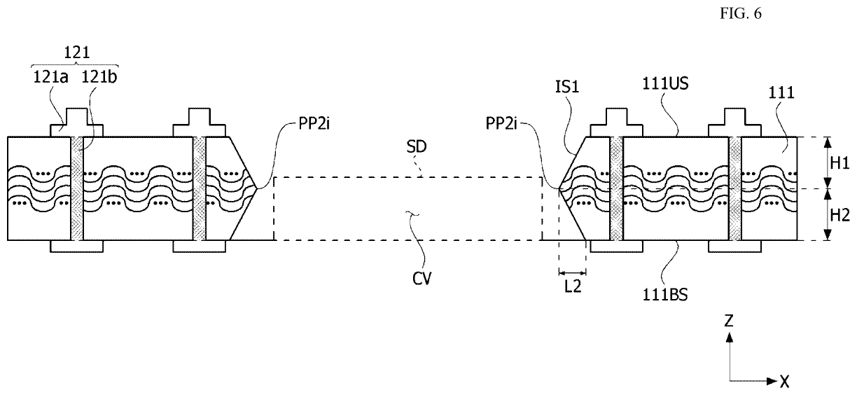

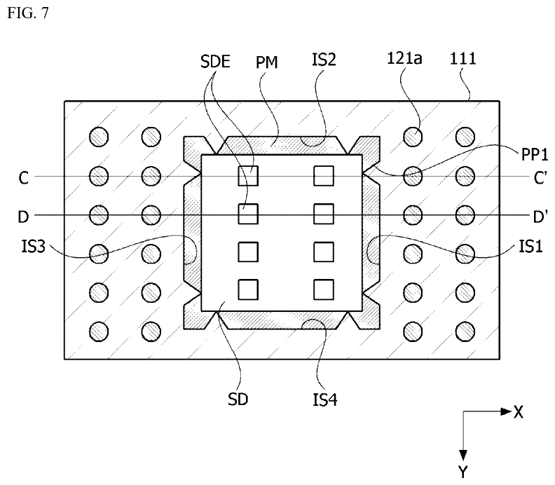

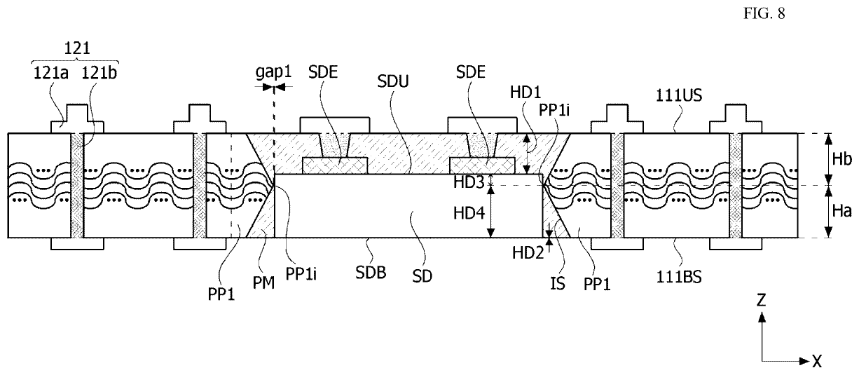

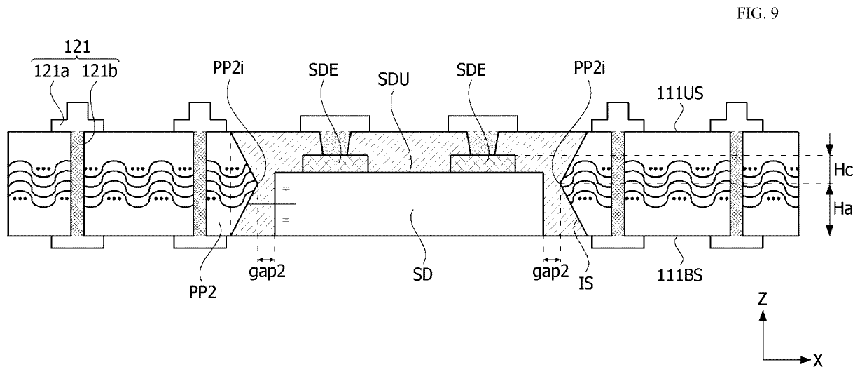

FIG. 1 is a cross-sectional view of a circuit board according to a first embodiment of the present invention, FIG. 2 is a view illustrating a core layer and a first electrode portion in the circuit board according to the first embodiment, FIG. 3 is a plan view of the core layer and the first electrode portion in the circuit board according to the first embodiment, FIG. 4 is an enlarged view of portion K in FIG. 3, FIG. 5 is a cross-sectional view taken along line AA′ of FIG. 3, FIG. 6 is a cross-sectional view taken along line BB′ of FIG. 3, FIG. 7 is a cross-sectional view illustrating the core layer, the first electrode portion, a filling member, and a connection member in the circuit board according to the first embodiment, FIG. 8 is a cross-sectional view taken along line CC′ of FIG. 7, and FIG. 9 is a cross-sectional view taken along line DD′ of FIG. 7.

Referring to FIG. 1, a circuit board 100A according to the first embodiment may include an insulating layer 110 and a wiring or electrode portion 120. In the following embodiment of the present invention, the insulating layer 110 may be formed of a plurality of insulating layers. Such a circuit board may be divided into an outer stacked region and an inner stacked region, and the inner stacked region may correspond to a core layer.

In the embodiment, the insulating layer 110 may be formed of a plurality of insulating layers stacked between an upper surface and a lower surface of the circuit board. For example, the insulating layer 110 may include a core layer 111, a first insulating layer 112, and a second insulating layer 113. In addition, the insulating layer 110 may further include a protective layer 114.

The insulating layer 110 of the circuit board 100A may be rigid or flexible. For example, the insulating layer 110 of the circuit board 100A may include glass or plastic. For example, the insulating layer 110 of the circuit board may include a chemically-strengthened/semi-tempered glass, such as soda lime glass or aluminosilicate glass. For example, the insulating layer 110 may include a reinforced or flexible plastic, such as polyimide (PI), polyethylene terephthalate (PET), propylene glycol (PPG), or polycarbonate (PC). For example, the insulating layer 110 of the circuit board may include sapphire. For example, the insulating layer 110 of the substrate may include an optically isotropic film. For example, the insulating layer 110 of the substrate may include a cyclic olefin copolymer (COC), a cyclic olefin polymer (COP), an optically isotropic polycarbonate (PC), or an optically isotropic polymethyl methacrylate (PMMA). For example, the insulating layer 110 of the substrate may be formed of a material including a filler and an insulating resin. For example, the insulating layer 110 of the substrate may have a structure in which a filler of a silica or alumina is disposed in a thermosetting resin or a thermoplastic resin.

The insulating layer 110 may have a structure in which a plurality of different insulating materials are stacked, and an exemplary arrangement structure thereof will be described in more detail below.

In one embodiment, the insulating layer 110 may include a core layer including a reinforcing member or a coreless layer. Here, the core layer may refer to an insulating layer that includes a reinforcing member and has a thickness exceeding 30 μm in its stacking direction (Z-axis direction). In addition, the insulating layer may include a plurality of layers respectively disposed above and below the core layer and not including a reinforcing member. In this case, the circuit board may be a core substrate. The reinforcing member may also be referred to as a reinforced fiber or a glass fiber.

The reinforcing member may refer to a glass fiber material extending in a horizontal direction of the insulating layer and may have a different meaning from fillers that are spaced apart from each other.

In addition, an interface between insulating layers may or may not be distinguishable depending on the analysis method.

The core layer 111 may be formed of various insulating materials. For example, the core layer 111 may be a part of a copper clad laminate (CCL). Alternatively, the core layer may correspond to a copper clad laminate. For example, the core layer 111 and a first electrode 121 located on the core layer 111 may be a copper clad laminate (CCL). The core layer 111 and a first circuit pattern layer may be a copper clad laminate (CCL). In addition, the core layer 111 may be formed of a plurality of layers, and the plurality of layers may be made of the same material or different materials.

In addition, the first insulating layer 112 and the second insulating layer 113 may be formed of an insulating resin, such as a thermosetting resin and/or a photocurable resin. As the thermosetting resin, ABF (Ajinomoto Build-up Film), which is a product released by Ajinomoto Co., Ltd., may be used, and a prepreg (PPG) including glass fibers may also be used. As the photocurable resin, an insulating resin such as a PID (photo-imageable dielectric) resin may be used. The above-described insulating resin may exemplarily be an epoxy resin, a bismaleimide triazine (BT) resin, a phenolic resin, or the like, and may include an inorganic filler such as silica. When an insulating resin is used as the core, the insulating resin may include a reinforcing material such as glass fibers or aramid fibers. For example, as the insulating layer 110, as an example, ABF (Ajinomoto Build-up Film), which is a product released by Ajinomoto Co., may be used, and FR-4, BT (Bismaleimide Triazine), PID (Photo Imageable Dielectric resin), and the like may also be used. For example, the insulating layer 110 may include a plurality of layers composed of ABF.

The protective layer 114 may function to protect pads from external moisture or contaminants and to prevent short-circuit problems during bonding between a semiconductor device and/or a main board and the circuit board, and as an example, the protective layer 114 may be formed of a solder resist. Specifically, the semiconductor device and/or the main board may have a plurality of terminals to be connected to the circuit board. In addition, the plurality of terminals may be disposed at a high density. When the plurality of terminals and pads of the circuit board are bonded, as an example, solder may be used. When solder is used, solder short-circuit (bridging) problems may occur between high-density terminals, and to solve such short-circuit problems, a solder resist having poor wettability with solder may be disposed. In addition, the protective layer 114 may be formed of a material having insulation properties with respect to electrical connection. Accordingly, the protective layer 114 may be referred to as an “insulating layer” and may be one of the components of the above-described insulating layer 110. The protective layer 114 may include resin, a curing agent, a photo-initiator, a pigment, a solvent, a filler, an additive, an acryl-based monomer, and the like. In addition, a third insulating layer (not shown) may include any one of a photo solder resist layer, a cover-lay, and a polymer material.

In addition, the insulating layer or the protective layer 114 located in the outer stacked region of the circuit board may have openings OP1 and OP2. Through the openings OP1 and OP2, electrical connections may be made with other semiconductor devices, the circuit board, or the like.

In addition, the wiring or electrode portion 120 according to the embodiment is disposed to electrically connect the main board or the like with a chip (or a semiconductor device or a die), and includes circuit patterns (or circuit pattern layers), pads, and via electrodes. The term “wiring” may correspond to an “electrode portion,” an “electrode,” an “electrode pattern,” or a “pattern.” In the electrode portion 120, the circuit pattern may be designed in various forms for signal and/or power transmission with a semiconductor device, and may be disposed within each stacked insulating layer 110.

In the electrode portion 120, via electrodes 121b, 122b, and 123b are disposed through portions of the vertically stacked insulating layers to provide vertical connections between circuit patterns disposed in the respective insulating layers. That is, the insulating layers may include via holes for the arrangement of the via electrodes. In addition, the via electrode may have a width larger than that of the circuit pattern for impedance optimization or heat dissipation, but is not limited thereto and may be freely designed.

In the electrode portion 120, pads 121a, 122a, and 123a may be disposed on the respective insulating layers. In addition, the pads 121a, 122a, and 123a may be electrically connected to the circuit patterns. In addition, the pads 121a, 122a, and 123a may be electrically connected to the semiconductor device and/or the main board, or the substrate.

In particular, among the pads, the pads disposed at outer sides may be bonded to the semiconductor device, the substrate, the board, or the like by solder, wire, a conductive adhesive, or the like and may be disposed to have a width greater than that of the circuit pattern in order to solve problems such as securing yield. However, the present invention is not limited thereto, and the pads may have the same width as the circuit pattern depending on technical limitations of the bonding process.

In addition, the pads disposed on inner layers function to connect the via electrodes and the circuit patterns. When the via electrodes are disposed to have a width greater than that of the circuit patterns, pads having a width greater than that of the circuit patterns are provided to ensure positional alignment during a manufacturing process in which the via electrodes are formed on the respective circuit patterns. Accordingly, each via electrode may have an upper surface located on the same plane as a lower surface of an upper pad in direct contact therewith, and a lower surface located on the same plane as an upper surface of a lower pad in direct contact therewith. Here, the lower surface of the upper pad and the upper surface of the lower pad do not necessarily mean flat surfaces but should be understood to include concave or convex surfaces depending on various manufacturing processes.

The circuit board may be classified into a package substrate and an interposer according to its function. The package substrate functions to mount a semiconductor device and/or an interposer. Due to the increase in data, the yield of the circuit board may be significantly reduced as the area of the circuit board becomes larger or the number of stacked insulating layers increases. Accordingly, to improve the yield of the circuit board having a high number of stacked layers, the circuit board may be separated into an interposer and a package substrate, thereby improving the yield of the circuit board. In addition, as the density of terminals of a semiconductor device increases, it may be difficult to implement pads of a package substrate having areas corresponding to the terminals of the semiconductor device. Accordingly, the interposer may serve as a buffer between a pad size of the package substrate and a fine pattern size of the terminals of the semiconductor device.

The above-described package substrate and interposer may be classified into a core substrate and a coreless substrate according to the configuration of insulating layers. In the case of the core substrate, the insulating layers may include a core layer, and the core layer may refer to a layer that includes a reinforcing member among the stacked insulating layers. The reinforcing member may refer to a glass fiber. The core layer may be disposed to be thicker than other insulating layers so as to prevent warpage or the like of the circuit board during a process. However, the core layer may cause issues such as voltage drop and signal loss or may make it difficult to achieve thinning. Accordingly, depending on the application field, a coreless substrate in which the insulating layers of the circuit board do not include the core layer may be used.

In the present embodiment, the core layer 111 may be disposed at the center of the insulating layer 110. In addition, the first insulating layer 112 may be disposed on the core layer 111. Further, the second insulating layer 113 may be disposed below the core layer 111. In addition, the protective layer 114 may be disposed on the first insulating layer 112 and below the second insulating layer 113.

The electrode portion 120 may include a core electrode 121, a first electrode portion 122, and a second electrode portion 123. The core electrode 121 may include a core pad 121a and a core via electrode 121b. The core pad 121a may be located on an upper surface and/or a lower surface of the core layer 111. The core via electrode 121b may be located in a hole passing through the core layer 111.

The first electrode portion 122 may include a first pad 122a and a first via electrode 122b. The second electrode portion 123 may include a second pad 123a and a second via electrode 123b.

The first pad 122a may be disposed on an upper portion of the first insulating layer 112. The first via electrode 122b may be disposed in a via hole passing through the first insulating layer 112. The first pad 122a and the first via electrode 122b may be electrically connected to each other.

The second pad 123a may be disposed on a lower portion of the second insulating layer 113. The second via electrode 123b may be disposed in a via hole passing through the second insulating layer 113. The second pad 123a and the second via electrode 123b may be electrically connected to each other.

Furthermore, according to the embodiment, the core layer 111 may include a cavity CV. In addition, the circuit board 100A may include a connection member SD, a filling member PM, a die via electrode CNV, and a connection pad SDT.

The connection member SD may be disposed in the cavity CV. The connection member SD may be interchangeably referred to as a “semiconductor device,” a “chip,” a “die,” or the like. The connection member SD may be disposed in the cavity CV and may be electrically connected to a plurality of other connection members disposed on an upper portion of the circuit board 100A. The connection member SD may be formed of silicon (Si) and may be referred to as a bridge.

In addition, the connection member SD may include a device electrode SDE on one surface thereof. For example, the device electrode SDE may be located on an upper portion of the connection member SD. The device electrode SDE may be in contact with the die via electrode CNV and may be electrically connected to the die via electrode CNV.

The filling member PM may be disposed in the cavity CV. The filling member PM may surround the connection member SD. The filling member PM may fix the connection member SD disposed in the cavity CV to the cavity CV. The filling member PM may be formed of an insulating material.

The die via electrode CNV may be disposed in a die via passing through the filling member PM. The die via electrode CNV may be electrically connected to the connection member SD. In addition, the die via electrode CNV may be electrically connected to the connection pad SDT thereabove.

The connection pad SDT may be disposed on the filling member PM. Furthermore, the connection pad SDT may be located on the same layer as the core pad 121a. The connection pad SDT may be in contact with the die via electrode CNV and may be electrically connected to the die via electrode CNV. In addition, the die via electrode CNV may be electrically connected to the first via electrode 122b. With this configuration, the connection member SD may be electrically connected to another connection member or a substrate disposed on an outer side of the circuit board 100A.

Referring further to FIGS. 2 to 6, in the circuit board 100A according to the embodiment, the cavity CV may be a hole passing through the core layer 111. In addition, the cavity CV of the core layer 111 may include side surfaces IS of the cavity. In this case, the side surfaces IS of the cavity may correspond to inner side surfaces, inner walls, or inner sidewalls of the hole in which the connection member SD is disposed, rather than a via hole in which the core via electrode 121b is disposed.

In the embodiment, the cavity CV may have a plurality of side surfaces according to its shape. In the embodiment, the cavity CV of the core layer 111 may have a rectangular shape on an XY plane. In addition, the side surfaces IS of the cavity CV may include a first side surface IS1, a second side surface IS2, a third side surface IS3, and a fourth side surface IS4. The first side surface IS1 and the third side surface IS3 may be disposed to be spaced apart from each other in a first direction (X-axis direction). The second side surface IS2 and the fourth side surface IS4 may be disposed to be spaced apart from each other in a second direction (Y-axis direction). In addition, the first direction (X-axis direction) may be perpendicular to the second direction (Y-axis direction), and a third direction (Z-axis direction) may be perpendicular to both the first direction (X-axis direction) and the second direction (Y-axis direction).

The first side surface IS1 may face the third side surface IS3. The second side surface IS2 may face the fourth side surface IS4. The second side surface IS2 and the fourth side surface IS4 may be disposed between the first side surface IS1 and the third side surface IS3. The first side surface IS1 and the third side surface IS3 may be disposed between the second side surface IS2 and the fourth side surface IS4.

The side surfaces IS of the cavity CV may face a plurality of side surfaces of the connection member SD disposed within the cavity CV. That is, a plurality of side surfaces IS of the cavity CV may face the plurality of side surfaces of the connection member SD disposed within the cavity CV.

In addition, the plurality of side surfaces IS of the cavity CV may include first portions and second portions. The first portions may be regions formed of second convex portions PP2. For example, the first portions may be referred to as “first regions,” “first parts,” “first sections,” or the like. The second portions may be formed of first convex portions PP1. The second portions may be referred to as “second regions,” “second parts,” “second sections,” or the like.

Each of the first portions may have a constant separation distance from the connection member SD in a horizontal direction along a perimeter of the connection member SD. In addition, the second portion may be disposed closer to the connection member SD than the first portion. As will be described later, the first portion may be disposed to be spaced farther apart from the connection member SD than the second portion formed of the first convex portion by the second convex portion. The horizontal direction may correspond to the first direction (X-axis direction) and/or the second direction (Y-axis direction). The first portions may be formed of a plurality of second convex portions PP2, and may have a separation distance from the connection member SD that falls within an error range of 10%. Hereinafter, the error range within 10% is described as being constant.

Further, in the plurality of side surfaces IS of the cavity CV, the second portions may overlap the connection member SD in the horizontal direction. In addition, the second portions in the plurality of side surfaces of the cavity CV may overlap each other in the horizontal direction. Likewise, the first portions (for example, the second convex portions) in the plurality of side surfaces of the cavity CV may overlap each other in the horizontal direction.

Furthermore, the cavity CV may include convex portions PP disposed on the side surfaces IS of the cavity CV. The convex portions may include the first convex portions PP1 and the second convex portions PP2.

The convex portion PP may have a convex shape toward the center of the cavity CV. The convex portion PP may have various shapes. Depending on processing or the like, the convex portion PP may have a triangular shape, a quadrangular shape, a circular shape, a needle shape, or the like in a plan view. For example, the convex portion PP may increase in length in a direction (that is, in the first direction (X-axis direction) or the second direction (Y-axis direction)) perpendicular to the stacking direction (or the Z-axis direction or the third direction) toward a bisector in the stacking direction. That is, in the convex portions PP, a central portion in the stacking direction may be located closer to the center of the cavity CV (for example, a center of gravity or an intersection of bisectors in the first and second directions) than both end portions.

At this time, the first convex portion PP1 may have a greater extension length or a larger convex length than the second convex portion PP2. The extension or convexity may be determined based on the portion, among the plurality of side surfaces, that is maximally spaced apart from or farthest from the connection member SD in the horizontal direction. For example, when the first side surface IS1 of the cavity CV is used as a reference, regions extending inward (or toward the connection member) from a line or plane, the line or plane being defined based on an extension from the end portion EP1 in the second direction (Y-axis direction) or perpendicular to the first direction (X-axis direction), may correspond to the convex portions (e.g., the first and second convex portions). For example, a length L1 of the first convex portion PP1 may be greater than a length L2 of the second convex portion PP2. That is, the first convex portion PP1 may be disposed closer to the connection member SD than the second convex portion PP2. With this configuration, while the cavity CV can be easily formed, the positional alignment or mounting of the connection member SD disposed in the cavity CV can be accurately performed. That is, movement of the die or the connection member SD can be prevented, thereby improving placement precision. Furthermore, by varying the length of the convex portion PP in the circuit board 100A, convex portions having different lengths may be disposed on the side surface IS of the cavity CV in accordance with the shape of the connection member SD or die. That is, a circuit board including a customized bridge corresponding to the die shape can be provided.

In addition, in one embodiment, the first convex portion PP1 may be disposed closer to both end portions EP1 and EP2 of the side surface IS than the second convex portion PP2. Both end portions may correspond to portions at which side surfaces extending in different directions come into contact with each other. Alternatively, both end portions may correspond to end portions in an extending direction of one side surface. With this configuration, movement of the connection member SD at its edge may be easily suppressed.

In addition, the first convex portions PP1 and the second convex portions PP2 may be located on each of the first side surface IS1, the second side surface IS2, the third side surface IS3, and the fourth side surface IS4. In addition, the first convex portions PP1 may be located at end portions of each of the first side surface IS1, the second side surface IS2, the third side surface IS3, and the fourth side surface IS4.

For example, the first convex portion of the first side surface IS1 adjacent to a point at which the first side surface IS1 and the second side surface IS2 come into contact with and the first convex portion of the second side surface IS2 may be disposed adjacent to each other.

Furthermore, the convex portions disposed on facing side surfaces may be disposed to be offset from each other in the first direction or the second direction. In other words, the convex portions disposed on the facing side surfaces may be disposed to overlap or be offset from each other.

For example, the first convex portion PP1 disposed on the first side surface IS1 may be disposed to correspond to the first convex portion PP1 disposed on the third side surface IS3. The first convex portion PP1 disposed on the first side surface IS1 may overlap the first convex portion PP1 disposed on the third side surface IS3 in the first direction.

In addition, the second convex portion PP2 disposed on the first side surface IS1 may be disposed to correspond to the second convex portion PP2 disposed on the third side surface IS3. The second convex portion PP2 disposed on the first side surface IS1 may overlap the second convex portion PP2 disposed on the third side surface IS3 in the first direction. The above-described positional relationship of the convex portions may be equally applied to the second side surface IS2 and the fourth side surface IS4 in the second direction.

In addition, with reference to one side surface, at least some of the second convex portions PP2 may be disposed between the first convex portions PP1 adjacent to each other in one direction. For example, on the first side surface IS1, the second convex portions PP2 may be disposed between the first convex portions PP1 spaced apart from each other in the second direction. In addition, on the second side surface IS2, the second convex portions PP2 may be disposed between the first convex portions PP1 spaced apart from each other in the first direction.

Furthermore, in the circuit board 100A according to the embodiment, a radius of curvature r2 of the first convex portion PP1 may be the same as a radius of curvature r1 of the second convex portion PP2. For example, the radii of curvature of the first convex portion PP1 and the second convex portion PP2 may be equal to each other in the XY plane or in a plane perpendicular to the stacking direction. With this configuration, the first convex portion PP1 and the second convex portion PP2 may be more easily formed. Furthermore, a distance error rate between the first convex portion PP1 and the connection member may be reduced, thereby enabling more accurate positional fixation.

However, the first convex portion PP1 and the second convex portion PP2 may have different lengths (for example, arc lengths) based on the XY plane or the plane perpendicular to the stacking direction. In the same XY plane or in the plane perpendicular to the stacking direction, a length (arc length) of the first convex portion PP1 may be greater than a length (arc length) of the second convex portion PP2.

In addition, corresponding to the radii of curvature of the first and second convex portions, an outermost portion PP1o of the first convex portion PP1 may be located at the same distance from the center of the cavity CV (or from the connection member) as an outermost portion PP2o of the second convex portion PP2. For example, on the first side surface IS1, separation distances of the outermost portion PP1o of the first convex portion PP1 and the outermost portion PP2o of the second convex portion PP2 from the center of the cavity CV in the first direction (X-axis direction) may be equal to each other. That is, the first convex portion PP1 and the second convex portion PP2 may be portions that protrude or extend from the same surface of the core layer 111. Here, the outer side corresponds to a direction from the center of the cavity (or the core layer) toward the side surface, and the inner side may correspond to a direction opposite to the outer side.

In other words, the outermost portion PP1o of the first convex portion PP1 may be located on the same line or the same plane as the outermost portion PP2o of the second convex portion PP2. For example, on the first side surface IS1, the outermost portion PP1o of the first convex portion PP1 may be located on the same plane M1 (a YZ plane) as the outermost portion PP2o of the second convex portion PP2. In addition, on the second side surface IS2, the outermost portion PP1o of the first convex portion PP1 may be located on the same plane M2 (an XZ plane) as the outermost portion PP2o of the second convex portion PP2. With this configuration, positional alignment of the connection member SD by the first convex portion PP1 may be precisely achieved.

In addition, an innermost portion PP1i of the first convex portion PP1 may be located at the same height from the upper surface or the lower surface of the core layer 111 as an innermost portion PP2i of the second convex portion PP2.

In the embodiment, the innermost portion PP1i of the first convex portion PP1 may be located at a central portion between an upper surface 111US and a lower surface 111BS of the core layer 111 in the stacking direction or the third direction. Accordingly, the innermost portion PP1i of the first convex portion PP1 may be disposed at the same height from the upper surface 111US or the lower surface 111BS of the core layer 111 as the innermost portion PP2i of the second convex portion PP2. For example, a height H1 between the innermost portion PP1i of the first convex portion PP1 and the upper surface 111US of the core layer 111 may be equal to a height H2 between the innermost portion PP1i of the first convex portion PP1 and the lower surface 111BS of the core layer 111, Accordingly, positional alignment may also be achieved for connection members SD of various sizes.

Referring further to FIGS. 7 to 9, a separation distance between the connection member SD and the innermost portion PP1i of the first convex portion PP1 may be different from a separation distance between the connection member SD and the innermost portion PP2i of the second convex portion PP2. A separation distance gap1 between the connection member SD and the innermost portion PP1i of the first convex portion PP1 may be smaller than a separation distance gap2 between the connection member SD and the innermost portion PP2i of the second convex portion PP2. Accordingly, positional alignment may be performed through the first convex portions PP1.

Furthermore, a height (a length in the third direction) of the connection member SD may be different from or the same as a height of the core layer 111. For example, the height of the connection member SD may be smaller than the height of the core layer 111.

In addition, a height difference HDI between an upper surface SDU of the connection member SD and the upper surface 111US of the core layer 111 may be different from a height difference HD2 between a lower surface SDB of the connection member SD and the lower surface 111BS of the core layer 111. In the embodiment, the height difference HD1 between the upper surface SDU of the connection member SD and the upper surface 111US of the core layer 111 may be greater than the height difference HD2 between the lower surface SDB of the connection member SD and the lower surface 111BS of the core layer 111, That is, the connection member SD may be disposed closer to the lower surface of the core layer 111 than to the upper surface 111US of the core layer 111. That is, the connection member SD may be disposed at a lower portion of the cavity CV in the stacking direction, such that the center of the connection member may be located to be offset from a bisector of the cavity in the stacking direction.

In addition, a height difference HD3 between the upper surface SDU of the connection member SD and the innermost portion PP1i of the first convex portion PP1 may be different from a height difference HD4 between the lower surface SDB of the connection member SD and the innermost portion PP1i of the first convex portion PP1. The height difference HD3 between the upper surface SDU of the connection member SD and the innermost portion PP1i of the first convex portion PP1 may be smaller than the height difference HD4 between the lower surface SDB of the connection member SD and the innermost portion PP1i of the first convex portion PP1.

In addition, the center of the connection member SD in the stacking direction may be disposed to be offset from the innermost portion PP1i of the first convex portion PP1. A bisector of the connection member SD in the stacking direction may be disposed below the innermost portion PP1i of the first convex portion PP1. Alternatively, the bisector of the connection member SD in the stacking direction may be located closer to the lower surface SDB of the connection member SD or the lower surface 111BS of the core layer 111 than to the innermost portion PP1i of the first convex portion PP1.

Accordingly, the innermost portion PP1i of the first convex portion PP1 may be located closer to the upper surface SDU of the connection member SD than to the lower surface SDB of the connection member SD. Thus, the movement of the connection member SD may be easily suppressed by the first convex portion PP1, and detachment of the connection member SD from the cavity CV during manufacturing may also be prevented.

The relationship among the first convex portion PP1, the connection member SD, and the core layer 111 as described above may be equally applied to the second convex portion PP2. For example, the innermost portion PP2i of the second convex portion PP2 may be located on a bisector between the upper surface 111US and the lower surface 111BS of the core layer 111. In addition, the second convex portion PP2 may be located closer to the upper surface SDU of the connection member SD than to the lower surface SDB thereof.

In addition, according to the embodiment, a height Ha of the innermost portion PP1i of the first convex portion may be greater than a height Hb between the innermost portion PP1i and the electrode SDE. In addition, a height Ha of the innermost portion PP2i of the second convex portion may be greater than a height Hc between the innermost portion PP2i and the electrode SDE.

Further, in the embodiment, a separation distance between the innermost portion PP1i of the first convex portion PP1 and the die via electrode CNV may be less than or equal to 0.5 times the height of the connection member. In addition, corresponding to the first convex portion PP1, a separation distance between the innermost portion PP2i of the second convex portion PP2 and the die via electrode CNV may also be less than or equal to 0.5 times the height of the connection member. Accordingly, while the connection member SD is mounted in the cavity CV and the filling member PM is applied or filled, the innermost portion PP1i of the first convex portion PP1 may be located closer to the upper surface of the connection member than to the lower surface thereof, thereby allowing the above-described positional alignment to be performed more effectively.

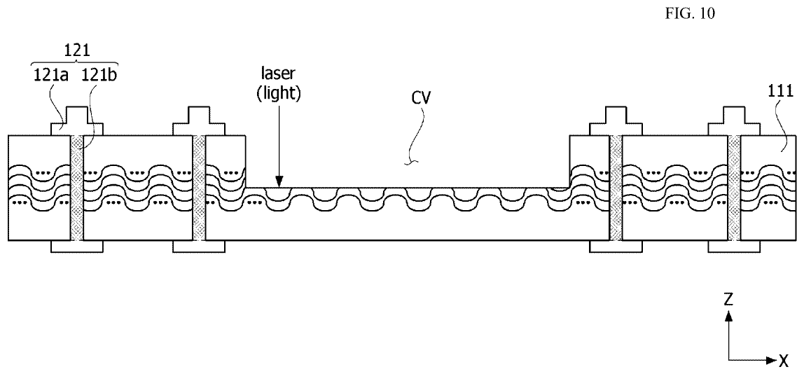

FIGS. 10 to 14 are views illustrating a method of manufacturing the circuit board according to the first embodiment.

The circuit board according to the embodiment may include forming a core layer and a core electrode, forming a cavity on a side surface of the core layer, the cavity including a first convex portion and a second convex portion protruding toward the center of the cavity and having different extension lengths, disposing a carrier member on one surface of the cavity, mounting a die or a connection member in the cavity, filling the cavity with a filling member, forming a die via electrode in a die via formed in the filling member, stacking insulating layers and forming electrode portions, and forming a protective layer and openings in the protective layer. Except for the descriptions provided below, the same details as described above may apply to the respective components.

Referring to FIG. 10, a core layer 111 may be formed, and a core electrode 121 may be formed in the core layer 111. In addition, in order to form a cavity CV of the core layer 111, laser light may be irradiated onto the core layer 111. In this case, the laser light may be irradiated so as to form a first convex portion and a second convex portion on a plane. At this time, the first convex portion and the second convex portion may be formed by a single laser. Accordingly, the first convex portion and the second convex portion may have the same radius of curvature. Thus, manufacturability may be ensured. In the electrode portion, a circuit pattern layer may be formed by an additive process, a subtractive process, a modified semi-additive process (MSAP), a semi-additive process (SAP), and the like, which are manufacturing processes of printed circuit boards. In addition, the pattern may be formed by a dry film or the like.

Referring further to FIG. 11, the first convex portion and the second convex portion may be formed on a side surface of the cavity CV. As described above, the first convex portion may have a different length from the second convex portion. For example, the first convex portion may be formed by not irradiating light at one point. Accordingly, the length of the first convex portion may be greater than the length of the second convex portion.

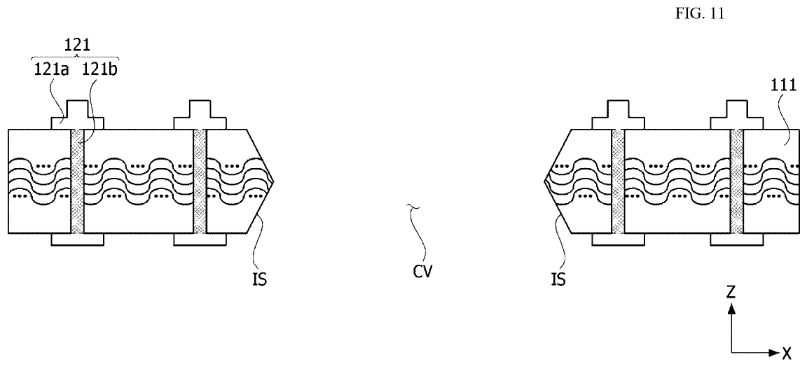

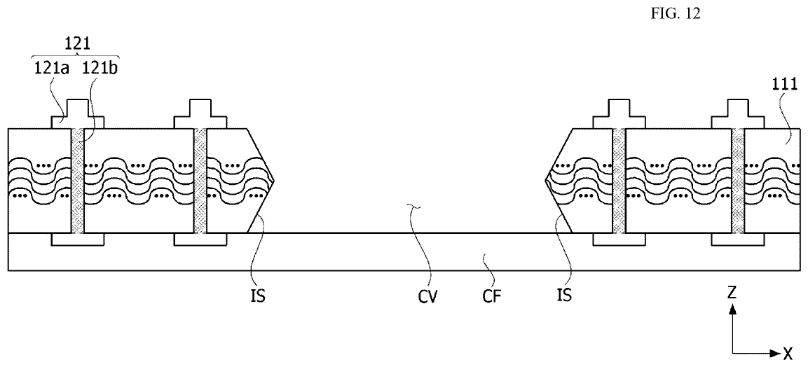

Referring further to FIG. 12, a carrier member CF may be disposed on one surface of the cavity CV. The carrier member CF may include a film or the like. In addition, the carrier member CF may be disposed on an upper surface or a lower surface of the cavity CV. For example, the carrier member CF may be bonded to the lower surface of the cavity CV. Accordingly, the connection member or die may be mounted in the cavity CV without being detached therefrom.

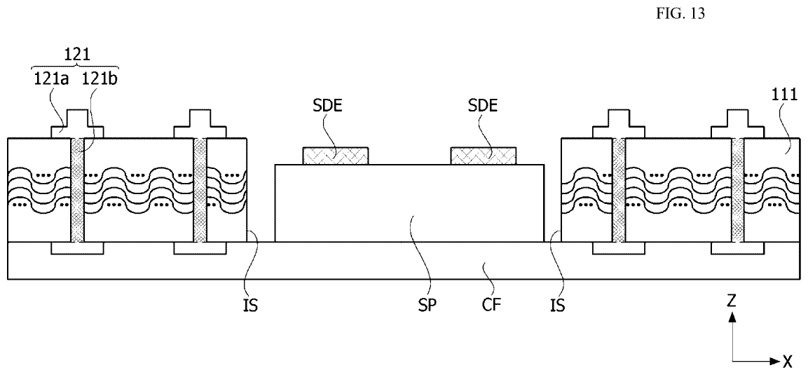

Referring further to FIG. 13, a die or a connection member may be mounted in the cavity. In addition, the connection member may be located on the carrier member CF. Accordingly, depending on the height of the connection member, the connection member may be located adjacent to one of an upper surface and a lower surface of the core layer. In this case, during mounting of the connection member by the first convex portion, positional alignment of the connection member within the cavity may be precisely achieved, and detachment or movement of the connection member may be suppressed.

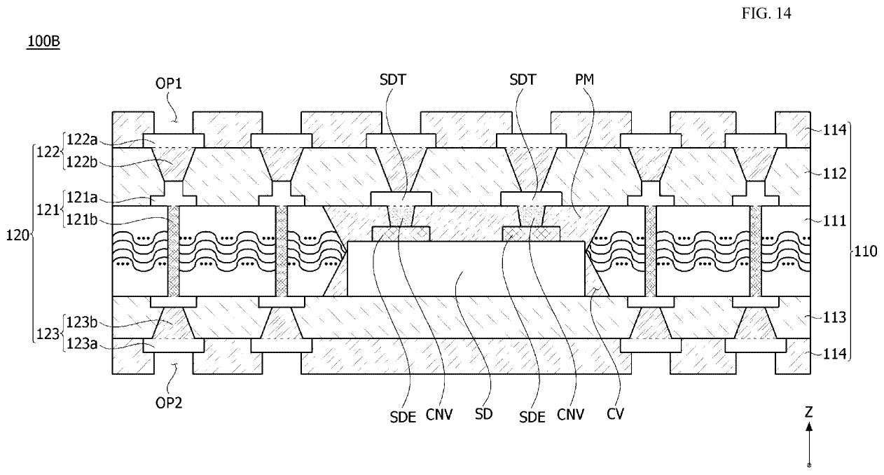

Referring to FIG. 14, a filling member PM may be filled in the cavity. Subsequently, a die via electrode CNV may be formed in a die via formed in the filling member PM. In addition, a connection pad SDT may be formed on the die via electrode CNV. Insulating layers may be stacked on the core layer, and electrode portions may be formed in the insulating layer. For example, a first insulating layer 112 may be stacked on an upper portion of the core layer, and a first electrode portion 122 may be formed in the first insulating layer 112. In addition, a second insulating layer 113 and a second electrode portion 123 may be formed. In addition, a protective layer 114 may be formed on the first insulating layer 112, and an opening OP1 may be formed in the protective layer 114. Furthermore, the protective layer and the opening may also be formed below the second insulating layer 113.

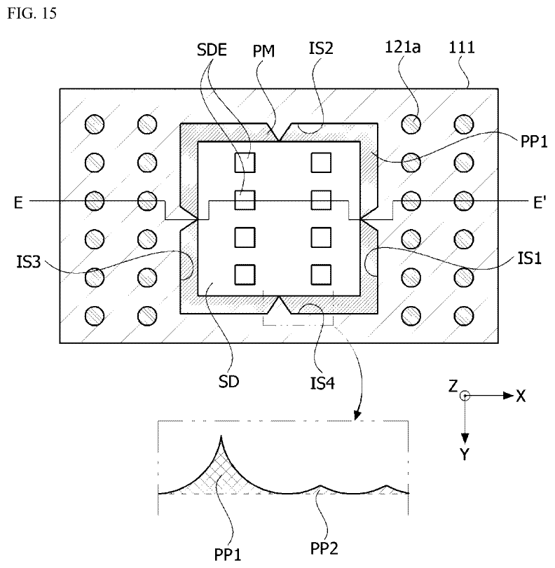

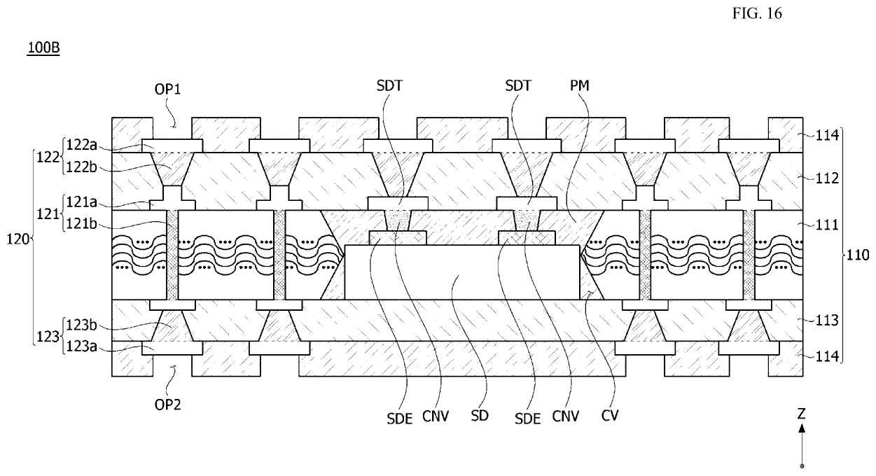

FIG. 15 is a plan view of a circuit board according to a second embodiment, and FIG. 16 is a cross-sectional view taken along line EE′ of FIG. 15.

Referring to FIGS. 15 and 16, a circuit board 100B according to the second embodiment may include an insulating layer 110, an electrode portion 120, a connection member SD, a filling member PM, a die via electrode CNV, and a connection pad SDT. Furthermore, except for the details described below, the descriptions of the components given above may be equally applied to the present embodiment.

In addition, based on one side surface, a first convex portion PP1 may be disposed between second convex portions PP2 adjacent to each other in one direction. For example, on a first side surface, the first convex portion PP1 may be disposed between the second convex portions PP2 spaced apart from each other in the second direction. In addition, on a second side surface, the first convex portion PP1 may be disposed between second convex portions PP2 spaced apart from each other in the first direction.

Furthermore, in the circuit board 100B according to the embodiment, the first convex portion PP1 may be located at the center of each side surface of a cavity CV. In addition, the first convex portions PP1 may be disposed to correspond to each other with respect to the facing side surfaces. Accordingly, positional alignment of the connection member SD may be efficiently achieved by the first convex portions.

In addition, as described above, in the circuit board 100B, a radius of curvature r2 of the first convex portion PP1 may be the same as a radius of curvature r1 of the second convex portion PP2. For example, in the XY plane or in a plane perpendicular to the stacking direction, the radii of curvature of the first convex portion PP1 and the second convex portion PP2 may be equal to each other. With this configuration, the first convex portion PP1 and the second convex portion PP2 may be more easily formed. Furthermore, a distance error rate between the first convex portion PP1 and the connection member may be reduced, thereby enabling more accurate positional fixation.

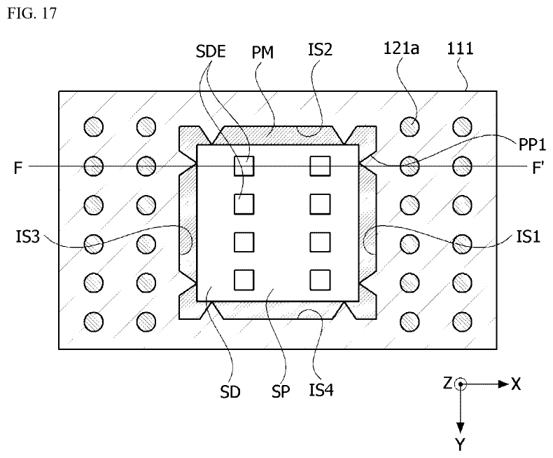

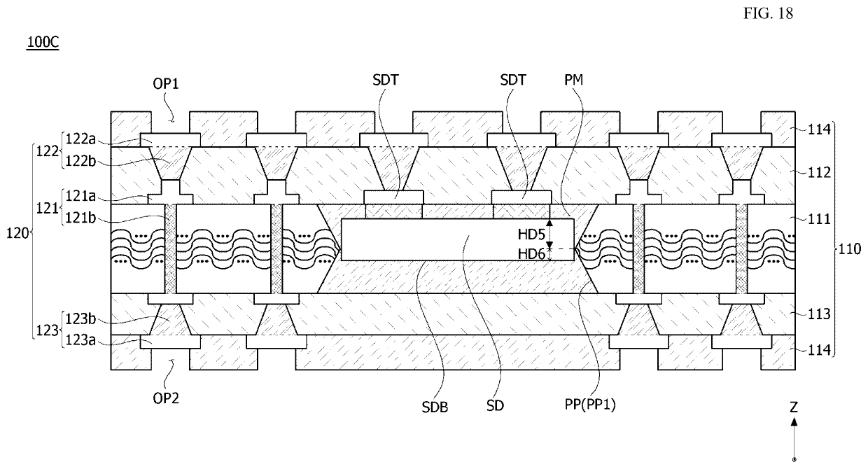

FIG. 17 is a plan view of a circuit board according to a third embodiment, and FIG. 18 is a cross-sectional view taken along line FF′ of FIG. 17.

Referring to FIGS. 17 and 18, a circuit board 100C according to the third embodiment may include an insulating layer 110, an electrode portion 120, a connection member SD, a filling member PM, a die via electrode CNV, and a connection pad SDT. Furthermore, except for the details described below, the descriptions of the components given above may be equally applied to the present embodiment.

The connection member SD may be disposed within a cavity CV, in an upper region of the cavity CV. In addition, the connection member SD may be located closer to an upper surface 111US of a core layer 111 than to a lower surface 111BS of the core layer 111.

Specifically, a height difference between an upper surface SDU of the connection member SD and the upper surface 111US of the core layer 111 may be different from a height difference between a lower surface SDB of the connection member SD and the lower surface 111BS of the core layer 111. In the embodiment, the height difference between the upper surface SDU of the connection member SD and the upper surface 111US of the core layer 111 may be smaller than the height difference between the lower surface SDB of the connection member SD and the lower surface 111BS of the core layer 111. That is, the connection member SD may be disposed closer to the upper surface 111US of the core layer 111 than to the lower surface of the core layer 111BS. That is, the connection member SD may be disposed at an upper portion of the cavity CV in the stacking direction, such that the center of the connection member is located to be offset from a bisector of the cavity in the stacking direction.

In addition, a height difference between the upper surface SDU of the connection member SD and an innermost portion PP1i of a first convex portion PP1 may be different from a height difference between the lower surface SDB of the connection member SD and the innermost portion PP1i of the first convex portion PP1. A height difference HD5 between the upper surface SDU of the connection member SD and the innermost portion PP1i of the first convex portion PP1 may be greater than a height difference HD6 between the lower surface SDB of the connection member SD and the innermost portion PP1i of the first convex portion PP1.

In addition, the center of the connection member SD in the stacking direction may be disposed to be offset from the innermost portion PP1i of the first convex portion PP1. A bisector of the connection member SD in the stacking direction may be disposed above the innermost portion PP1i of the first convex portion PP1. Alternatively, the bisector of the connection member SD in the stacking direction may be located closer to the innermost portion PP1i of the first convex portion PP1 than to the lower surface SDB of the connection member SD or the lower surface 111BS of the core layer 111.

Accordingly, heat dissipation through the filling member PM disposed below the connection member SD may be facilitated, and an electrical distance between a chip (or a semiconductor device, a substrate, or the like) disposed on an upper portion of the circuit board 100C and the connection member SD in the cavity CV may be reduced. Accordingly, electrical efficiency and the like may be improved.

Furthermore, the relationship among the first convex portion PP1, the connection member SD, and the core layer 111 may be equally applied to a second convex portion PP2. For example, an innermost portion PP2i of the second convex portion PP2 may be located on a bisector between the upper surface 111US and the lower surface 111BS of the core layer 111. In addition, the second convex portion PP2 may be located closer to the lower surface SDB of the connection member SD than to the upper surface SDU thereof.

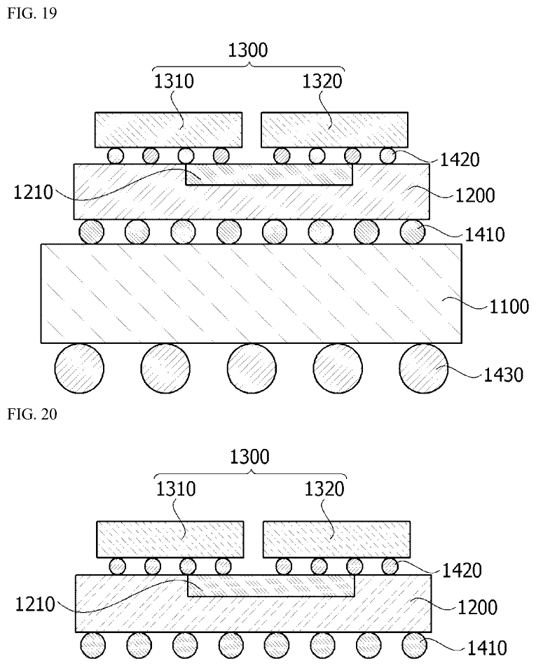

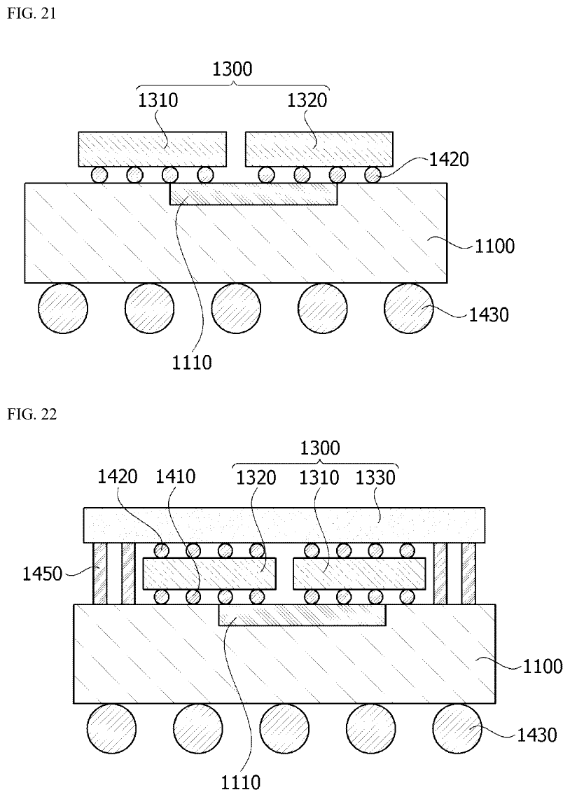

FIG. 19 is a cross-sectional view illustrating a semiconductor package according to a first embodiment, FIG. 20 is a cross-sectional view illustrating a semiconductor package according to a second embodiment, FIG. 21 is a cross-sectional view illustrating a semiconductor package according to a third embodiment, and FIG. 22 is a cross-sectional view illustrating a semiconductor package according to a fourth embodiment.

In the various semiconductor packages described below, the above-described circuit board may be located in a partial region or may correspond to one substrate.

Referring to FIG. 19, the semiconductor package according to the first embodiment may include a first substrate 1100, a second substrate 1200, and a semiconductor device 1300.

The first substrate 1100 may refer to, or include the meaning of, a “package substrate” or a “circuit board.” For example, the first substrate 1100 may provide a space in which at least one external substrate is coupled. The external substrate may refer to the second substrate 1200 coupled to an upper portion of the first substrate 1100. In addition, the external substrate may refer to a main board included in an electronic device and coupled to a lower portion of the first substrate 1100.

In addition, although not shown in the drawings, the first substrate 1100 may provide a space in which at least one semiconductor device is mounted.

The first substrate 1100 may include at least one insulating layer and an electrode portion disposed on the at least one insulating layer.

The second substrate 1200 may be disposed on the first substrate 1100.

The second substrate 1200 may be an interposer. For example, the second substrate 1200 may provide a space in which at least one semiconductor device is mounted. The second substrate 1200 may be connected to at least one semiconductor device 1300. For example, the second substrate 1200 may provide a space in which a first semiconductor device 1310 and a second semiconductor device 1320 are mounted. The second substrate 1200 may electrically connect between the first semiconductor device 1310 and the second semiconductor device 1320, while electrically connecting between the first and second semiconductor devices 1310 and 1320 and the first substrate 1100. That is, the second substrate 1200 may perform a horizontal connection function among a plurality of semiconductor devices, and a vertical connection function between the semiconductor devices and the package substrate.

Although two semiconductor devices 1310 and 1320 are illustrated in FIG. 18 as being disposed on the second substrate 1200, the present invention is not limited thereto. For example, one semiconductor device may be disposed on the second substrate 1200, and alternatively, three or more semiconductor devices may be disposed thereon.

The second substrate 1200 may be disposed between at least one semiconductor device 1300 and the first substrate 1100.

In one embodiment, the second substrate 1200 may be an active interposer having a semiconductor device function. When the second substrate 1200 has a semiconductor device function, the semiconductor package of the embodiment may have a vertically stacked structure on the first substrate 1100 and may have functions of a plurality of logic chips. Having the functions of logic chips may mean that the second substrate 1200 may have functions of active devices and passive devices. In the case of active devices, unlike passive devices, the characteristics of current and voltage may not be linear, and the active interposer may have functions of active devices. In addition, the active interposer may perform functions of a corresponding logic chip while performing a signal transmission function between a second logic chip disposed above the active interposer and the first substrate 1100.

According to another embodiment, the second substrate 1200 may be a passive interposer. For example, the second substrate 1200 may perform a signal relay function between the semiconductor device 1300 and the first substrate 1100, and may have functions of passive devices such as resistors, capacitors, and inductors. For example, the number of terminals provided in the semiconductor device 1300 is gradually increasing due to 5G, the Internet of Things (IoT), an increase in image quality, an increase in communication speed, or the like. That is, the number of terminals included in the semiconductor device 1300 increases, and accordingly, a width of the terminal or a spacing between a plurality of terminals decrease. In this case, the first substrate 1100 may be connected to the main board of the electronic device. Accordingly, in order for electrodes provided in the first substrate 1100 to have widths and spacings suitable for being connected to each of the semiconductor device 1300 and the main board, there is a problem in which a thickness of the first substrate 1100 may increase or a layer structure of the first substrate 1100 becomes complicated. Accordingly, in the first embodiment, the second substrate 1200 may be disposed between the first substrate 1100 and the semiconductor device 1300. In addition, the second substrate 1200 may include electrodes having a fine width and a spacing corresponding to the terminals of the semiconductor device 1300.

The semiconductor device 1300 may be a logic chip, a memory chip, or the like. The logic chip may be a central processor (CPU), a graphics processor (GPU), or the like. For example, the logic chip may be an application processor (AP) including at least one of a central processing unit (CPU), a graphics processing unit (GPU), a digital signal processor, a cryptographic processor, a microprocessor, and a microcontroller, may be an analog-to-digital converter, an application-specific IC (ASIC), or the like, or may be a chip set including a specific combination of those listed so far. In addition, the memory chip may be a stack memory such as HBM. Further, the memory chip may include a memory chip such as a volatile memory (e.g., DRAM), a non-volatile memory (e.g., ROM), a flash memory, or the like.

Meanwhile, the semiconductor package of the first embodiment may include connection portions.

For example, the semiconductor package may include a first connection portion 1410 disposed between the first substrate 1100 and the second substrate 1200. The first connection portion 1410 may electrically connect between the first substrate 1100 and the second substrate 1200 while coupling the second substrate 1200 to the first substrate 1100.

For example, the semiconductor package may include a second connection portion 1420 disposed between the second substrate 1200 and the semiconductor device 1300. The second connection portion 1420 may electrically connect between the semiconductor device 1300 to the second substrate 1200 while mounting the semiconductor device 1300 on the second substrate 1200.

The semiconductor package may include a third connection portion 1430 disposed on a lower surface of the first substrate 1100. The third connection portion 1430 may electrically connect between the first substrate 1100 and the main board while bonding the first substrate 1100 to the main board.

In this case, the first connection portion 1410, the second connection portion 1420, and the third connection portion 1430 may electrically connect between a plurality of components by using at least one bonding method among wire bonding, solder bonding, and metal-to-metal direct bonding. That is, since the first connection portion 1410, the second connection portion 1420, and the third connection portion 1430 have a function of electrically connecting a plurality of components, when metal-to-metal direct bonding is used, the semiconductor package may be understood as being a portion that is electrically connected without the use of solder or wires.

The wire bonding method may refer to electrically connecting between a plurality of components by using a conducting wire made of gold (Au) or the like. In addition, the solder bonding method may electrically connect between a plurality of components by using a material including at least one of Sn, Ag, and Cu. Further, the metal-to-metal direct bonding method may refer to directly bonding between a plurality of components without using members such as solder, bonding wires, or conductive adhesives by applying heat and pressure between the plurality of components, thereby causing recrystallization. In addition, the metal-to-metal direct bonding method may correspond to a bonding method by the second connection portion 1420. In this case, the second connection portion 1420 may refer to a metal layer formed between the plurality of components by recrystallization.

Specifically, the first connection portion 1410, the second connection portion 1420, and the third connection portion 1430 may bond a plurality of components to each other by a thermal compression bonding method. The thermal compression bonding method may refer to a method of directly bonding between a plurality of components by applying heat and pressure to the first connection portion 1410, the second connection portion 1420, and the third connection portion 1430.

In this case, in at least one of the first substrate 1100 and the second substrate 1200, electrodes on which the first connection portion 1410, the second connection portion 1420, and the third connection portion 1430 are disposed may include a protrusion protruding outward from the insulating layer of the corresponding substrate. The protrusion may protrude outward from the first substrate 1100 or the second substrate 1200.

The protrusion may be referred to as a bump. The protrusion may also be referred to as a post. The protrusion may also be referred to as a pillar. Preferably, the protrusion may refer to the electrode of the second substrate 1200 on which the second connection portion 1420 for coupling with the semiconductor device 1300 is disposed. That is, as a pitch of the terminals of the semiconductor device 1300 becomes finer, short-circuiting may occur between a plurality of second connection portions 1420, which are respectively connected to a plurality of terminals of the semiconductor device 1300 by a conductive adhesive such as solder. Accordingly, in the embodiment, thermal compression bonding may be performed in order to reduce the volume of the second connection portions 1420. Accordingly, in the embodiment, the electrode of the second substrate 1200 on which the second connection portion 1420 is disposed may include a protrusion to secure alignment, to provide diffusion-blocking capability, and to prevent intermetallic compound (IMC) formed between a conductive adhesive such as solder and the protrusion from diffusing into the interposer and/or the substrate.

In addition, referring further to FIG. 19, the semiconductor package of the first embodiment may further include a connection member 1210.

The connection member 1210 may be referred to as a bridge substrate. For example, the connection member 1210 may include a redistribution layer. The connection member 1210 may function to electrically connect a plurality of semiconductor devices to each other in the horizontal direction. As an example, since an area required for the semiconductor device is generally too large, the connection member 1210 may include a redistribution layer. Because the semiconductor package and the semiconductor device have a significant difference in the width or pitch of circuit patterns, a buffering function for electrical connection is required. The buffering function may refer to providing an intermediate size (e.g., width or pitch) of the circuit pattern between that of the semiconductor package and that of the semiconductor device, and the redistribution layer may perform such a buffering function.

In the embodiment, the connection member 1210 may be an organic bridge. For example, the connection member 1210 may include an organic material. For example, the connection member 1210 may include an organic substrate including an organic material instead of a silicon substrate. The connection member 1210 may be embedded in the second substrate 1200.

To this end, the second substrate 1200 may include a cavity, and the connection member 1210 may be disposed in the cavity of the second substrate 1200. The connection member 1210 may horizontally connect between a plurality of semiconductor devices disposed on the second substrate 1200.

Referring to FIG. 20, the semiconductor package of the second embodiment may include the second substrate 1200 and the semiconductor device 1300. In this case, the semiconductor package of the second embodiment may have a structure in which the first substrate 1100 is omitted compared to the semiconductor package of the first embodiment.

That is, the second substrate 1200 of the second embodiment may function as an interposer while functioning as a package substrate.

The first connection portion 1410 disposed on a lower surface of the second substrate 1200 may couple the second substrate 1200 to the main board of the electronic device.

Referring to FIG. 21, the semiconductor package of the third embodiment may include the first substrate 1100 and the semiconductor device 1300.

In this case, the semiconductor package of the third embodiment may have a structure in which the second substrate 1200 is omitted compared to the semiconductor package of the first embodiment.

That is, the first substrate 1100 of the third embodiment may function as a package substrate while functioning to connect between the semiconductor device 1300 and the main board. To this end, the first substrate 1100 may include a connection member 1110 for connecting between a plurality of semiconductor devices. The connection member 1110 may be an organic bridge that connects between the plurality of semiconductor devices.

Referring to FIG. 22, the semiconductor package of the fourth embodiment may further include a third semiconductor device 1330, compared to the semiconductor package of the fourth embodiment. To this end, a fourth connection portion may be further disposed on one surface of the first substrate 1100.

As such, the semiconductor package of the fourth embodiment may have a structure in which semiconductor devices are mounted on an upper side and a lower side, respectively. In this case, the third semiconductor device 1330 may have a structure in which the third semiconductor device 1330 is disposed on the lower surface of the second substrate 1200 in the semiconductor package of FIG. 19.

In addition, the connection member 1110 may be embedded in the first substrate 1100. The connection member 1110 may horizontally connect the first and second semiconductor devices 1310 and 1320.

In addition, the first substrate 1100 may include a conductive coupling portion 1450. The conductive coupling portion 1450 may protrude further toward the second semiconductor device 1320 from the first substrate 1100. The conductive coupling portion 1450 may be referred to as a bump, and alternatively may be referred to as a post. The conductive coupling portion 1450 may be disposed on an electrode located at an uppermost side of the first substrate 1100 and may have a protruding structure.

The third semiconductor device 1330 may be disposed on the conductive coupling portion 1450. In this case, the third semiconductor device 1330 may be connected to the first substrate 1100 through the conductive coupling portion 1450. In addition, the second connection portion 1420 may be disposed between the first and second semiconductor devices 1310 and 1320 and the third semiconductor device 1330.

Accordingly, the third semiconductor device 1330 may be electrically connected to the first and second semiconductor devices 1310 and 1320 through the second connection portion 1420.

That is, the third semiconductor device 1330 may be connected to the first substrate 1100 through the conductive coupling portion 1450, and may also be connected to the first and second semiconductor devices 1310 and 1320 through the second connection portion 1420.

In this case, the third semiconductor device 1330 may receive a power signal and/or power through the conductive coupling portion 1450. In addition, the third semiconductor device 1330 may exchange communication signals with the first and second semiconductor devices 1310 and 1320 through the second connection portion 1420.

The semiconductor package of the fourth embodiment may supply a power signal and/or power to the third semiconductor device 1330 through the conductive coupling portion 1450, thereby enabling sufficient power to be provided for driving the third semiconductor device 1330 and allowing smooth control of power operation.

Accordingly, in the embodiment, driving characteristics of the third semiconductor device 1330 may be improved. That is, the embodiment may solve a problem in which power supplied to the third semiconductor device 1330 becomes insufficient. Furthermore, in the embodiment, at least one of a power signal, power, and a communication signal of the third semiconductor device 1330 may be provided through different paths via the conductive coupling portion 1450 and the second connection portion 1420. Through this, the embodiment may solve a problem in which loss of a communication signal occurs due to a power signal. For example, the embodiment may minimize mutual interference between the power signal and the communication signal.

Meanwhile, in the fourth embodiment, the third semiconductor device 1330 may have a POP (Package On Package) structure in which a plurality of package substrates are stacked, and may be disposed on the first substrate 1100. For example, the third semiconductor device 1330 may be a memory package including a memory chip. In addition, the memory package may be coupled on the conductive coupling portion 1450. In this case, the memory package may not be connected to the first and second semiconductor devices 1310 and 1320.

Furthermore, a semiconductor package in a modified example may include the first substrate 1100 and the first and second semiconductor devices 1310 and 1320 disposed on the first substrate 1100 in FIG. 18. In addition, the semiconductor package may include the first connection portion 1410 disposed between the first substrate 1100 and the first and second semiconductor devices 1310 and 1320. That is, the semiconductor package may have a structure in which the second substrate and the second connection portion are omitted from FIG. 18.

Meanwhile, when the circuit board having the above-described characteristics of the invention is used in an IT device or home appliance such as a smart phone, a server computer, a TV, and the like, functions such as signal transmission or power supply can be stably performed. For example, when the circuit board having the features of the present invention performs a semiconductor package function, it can function to safely protect the semiconductor chip from external moisture or contaminants, or alternatively, it is possible to solve problems of leakage current, electrical short circuit between terminals, and electrical opening of terminals supplied to the semiconductor chip. In addition, when the function of signal transmission is in charge, it is possible to solve the noise problem. Through this, the circuit board having the above-described characteristics of the invention can maintain the stable function of the IT device or home appliance, so that the entire product and the circuit board to which the present invention is applied can achieve functional unity or technical interlocking with each other.

When the circuit board having the characteristics of the invention described above is used in a transport device such as a vehicle, it is possible to solve the problem of distortion of a signal transmitted to the transport device, or alternatively, the safety of the transport device can be further improved by safely protecting the semiconductor chip that controls the transport device from the outside and solving the problem of leakage current or electrical short between terminals or the electrical opening of the terminal supplied to the semiconductor chip. Accordingly, the transport device and the circuit board to which the present invention is applied can achieve functional integrity or technical interlocking with each other.

Features, structures, effects, and the like described in the above embodiments are included in at least one embodiment, and are not necessarily limited to only one embodiment. Furthermore, features, structures, effects, and the like illustrated in each embodiment can be combined or modified for other embodiments by those of ordinary skill in the art to which the embodiments belong. Accordingly, the contents related to such combinations and modifications should be interpreted as being included in the scope of the embodiments.

Although the embodiments have been described above, the embodiments are merely examples and not intended to limit the present invention and it may be seen that a variety of modifications and applications not described above may be made by one of ordinary skill in the art without departing from the essential features of the embodiments. For example, each component specifically shown in the embodiment may be implemented with modifications. In addition, it should be construed that differences related to such changes and applications are included in the scope of the embodiments defined in the appended claims.

1. A circuit board comprising:
a core layer including a cavity; and
a connection member disposed in the cavity of the core layer,
wherein side surfaces of the cavity include a plurality of side surfaces facing a plurality of side surfaces of the connection member,
each of the plurality of side surfaces of the cavity includes a first portion having a constant separation distance from the connection member in a horizontal direction along a perimeter of the connection member, and a second portion disposed closer to the connection member than the first portion, and
the second portion of each of the plurality of side surfaces of the cavity overlaps the connection member in the horizontal direction.

2. The circuit board of claim 1, wherein the cavity includes first convex portions and second convex portions that protrude from the side surface of the cavity toward an inner side of the cavity.

3. The circuit board of claim 2, wherein the first convex portions have a greater extension length than the second convex portions and are adjacent to both end portions of the side surface.

4. The circuit board of claim 1, wherein the second portions of the plurality of side surfaces of the cavity overlap each other in the horizontal direction.

5. The circuit board of claim 2, wherein the first convex portions are disposed closer to the connection member than the second convex portions.

6. The circuit board of claim 2, wherein the second convex portions are disposed between the first convex portions that are adjacent to each other in one direction.

7. The circuit board of claim 2, wherein a radius of curvature of the first convex portion is equal to a radius of curvature of the second convex portion.

8. The circuit board of claim 2, wherein an outermost portion of the first convex portion is disposed on the same line as an outermost portion of the second convex portion.

9. The circuit board of claim 2, wherein an innermost portion of the first convex portion is disposed at the same height from an upper surface or a lower surface of the core layer as an innermost portion of the second convex portion.

10. The circuit board of claim 2, comprising a filling member surrounding the connection member in the cavity.

11. The circuit board of claim 10, wherein a height difference between an upper surface of the connection member and an upper surface of the core layer is greater than a height difference between a lower surface of the connection member and a lower surface of the core layer.

12. The circuit board of claim 10, wherein an innermost portion of the first convex portion is closer to an upper surface of the connection member than to a lower surface of the connection member.

13. The circuit board of claim 10, wherein a center of the connection member in a stacking direction is disposed to be offset from an innermost portion of the first convex portion.

14. The circuit board of claim 13, comprising a die via electrode disposed above the connection member and disposed in a die via passing through the filling member.

15. The circuit board of claim 14, wherein a separation distance between the innermost portion of the first convex portion and the die via electrode is less than or equal to 0.5 times a height of the connection member,

16. The circuit board of claim 2, wherein a first convex portion is disposed between second convex portions spaced apart from each other in one direction.

17. The circuit board of claim 16, wherein the first convex portions are located at centers of respective side surfaces of the cavity.

18. The circuit board of claim 1, wherein the cavity of the core layer has a rectangular shape in a plan view.

19. The circuit board of claim 2, wherein convex portions disposed on facing side surfaces are disposed to overlap or to be spaced apart from each other in a first direction or a second direction.

20. The circuit board of claim 14, wherein a connection pad is further disposed on the filling member and is located on the same layer as a core pad.
